(19) United States
(12) Patent Application Publication
(10) Pub. No.: US 2019/0333998 A1
(43) Pub. Date: Oct. 31, 2019

(54) SILICON CARBIDE EPITAXIAL WAFER AND SILICON CARBIDE SEMICONDUCTOR DEVICE

(71) Applicant: NATIONAL INSTITUTE OF ADVANCED INDUSTRIAL SCIENCE AND TECHNOLOGY, Tokyo (JP)

(72) Inventors: Keiko MASUMOTO, Nagareyama-shi (JP); Takashi MITANI, Tsukuba-shi (JP); Kazuma ETO, Tsukuba-shi (JP); Kazutoshi KOJIMA, Tsukuba-shi (JP); Tomohisa KATO, Tsukuba-shi (JP)

(21) Appl. No.: 16/224,882

(22) Filed: Dec. 19, 2018

(30) Foreign Application Priority Data
Apr. 26, 2018 (JP) 2018-085782

(51) Int. Cl. H01L 29/16; H01L 29/739; H01L 29/66; H01L 21/02; C30B 23/02; C30B 29/36

(52) U.S. Cl. CPC H01L 29/1608; H01L 29/7395; H01L 29/66068; C30B 29/36; H01L 21/0262; C30B 23/025; H01L 21/02529

(57) ABSTRACT

A high quality silicon carbide epitaxial wafer using a p-type silicon carbide single crystal substrate of low resistivity. The silicon carbide epitaxial wafer includes a p-type 4H—SiC single crystal substrate that has a first main surface having an off angle with respect to (0001) plane, and has a resistivity of less than 0.4 Ωcm, and a silicon carbide epitaxial layer that is disposed on the first main surface of the p-type 4H—SiC single crystal substrate, in which an off direction of the off angle is the <01-10> direction.

### BACKGROUND OF THE INVENTION

### Field of the Invention

The present invention relates to a silicon carbide epitaxial wafer, and a silicon carbide semiconductor device.

Priority is claimed on Japanese Patent Application No. 2018-085782, filed Apr. 26, 2018, the content of which is incorporated herein by reference.

### Description of Related Art

Power electronics which are in charge of conversion (direct current-alternating current conversion or voltage conversion) or control of electric power is expected to be a key technology for saving energy.

Hitherto, improvement in performance of the power electronics comes to be achieved by silicon (Si), but a silicon carbide (SiC) has attracted attention as a next generation material, since a theoretical limit comes into view.

Since the silicon carbide (SiC) has excellent performance such that dielectric breakdown electric field intensity is ten times, or a band gap is three times, in comparison with silicon (Si), a SiC power device using a silicon carbide single crystal substrate is expected that a high withstand voltage and a low power loss are made.

The SiC power device is manufactured using a silicon carbide epitaxial wafer (SiC epitaxial wafer) in which a silicon carbide epitaxial layer is formed on the silicon carbide single crystal substrate. The silicon carbide single crystal substrate is obtained by being processed from a bulk single crystal (ingot) of silicon carbide which is manufactured by a solution method, a sublimation method, or the like, and the silicon carbide epitaxial layer is formed by a chemical vapor phase growth method (Chemical Vapor Deposition: CVD).

In general, the silicon carbide single crystal substrate with a predetermined off angle from (0001) plane is used in order to make the silicon carbide epitaxial layer formable by a step flow growth. Hereinafter, the silicon carbide single crystal substrate having the off angle may be simply referred to as an off substrate.

Since an off substrate in <11-20> direction is commercially available, the off substrate in the <11-20> direction is generally used (for example, see Japanese Unexamined Patent Application, First Publication No. 2017-124974, Japanese Unexamined Patent Application, First Publication No. 2017-135424, Japanese Unexamined Patent Application, First Publication No. 2017-168561, and Japanese Unexamined Patent Application, First Publication No. 2018-18998). Hereinafter, such a silicon carbide single crystal substrate may be referred to as an “off substrate in the <11-20> direction”.

On the other hand, there is a report on a silicon carbide epitaxial wafer using an off substrate in <01-10> direction (for example, see Japanese Unexamined Patent Application, First Publication No. 2016-138040 and Japanese Unexamined Patent Application, First Publication No. 2016-52994).

Japanese Unexamined Patent Application, First Publication No. 2016-138040 discloses a silicon carbide epitaxial wafer using a silicon carbide substrate of which an off direction of an off angle is in a range of 5° or less with respect to the <11-20> direction, or is in a rage of 5° or less with respect to the <01-10> direction (for example, see claim 1).

Japanese Unexamined Patent Application, First Publication No. 2016-52994 discloses a silicon carbide epitaxial wafer in which a silicon carbide substrate of which an off direction of an off angle is the <11-20> direction or the <01-10> direction is used, a direction of a dislocation line of threading dislocation is in a predetermined angle from c-axis, the impurity concentration of an epitaxial film is lower than the impurity concentration of a silicon carbide single crystal substrate, and the impurity concentration of the epitaxial film is 1×10¹⁷ cm⁻³ or less (for example, see claim 1, paragraph 0016, and paragraph 0043).

In the inventions disclosed in Japanese Unexamined Patent Application, First Publication No. 2016-138040 and Japanese Unexamined Patent Application, First Publication No. 2016-52994, either the off substrate in the <11-20> direction or the off substrate in the <01-10> direction is not indispensable for realizing the invention, and it is possible to use any substrate.

### SUMMARY OF THE INVENTION

Hitherto, the off substrate in the <11-20> direction comes to be used in a SiC epitaxial growth on an n-type silicon carbide single crystal substrate, or a SiC epitaxial growth on a p-type silicon carbide single crystal substrate having relatively high resistivity, but there is no particularly big problem in quality.

On the other hand, since low resist in the p-type silicon carbide single crystal substrate is less likely to be made, the silicon carbide epitaxial wafer onto which the SiC epitaxial growth is performed on the p-type silicon carbide single crystal substrate of low resistivity is not studied (for example, see Japanese Unexamined Patent Application, First Publication No. 2015-130528).

In recent years, the p-type silicon carbide single crystal substrate of the low resistivity comes to be manufactured at a research and experiment level (for example, see Japanese Unexamined Patent Application, First Publication No. 2017-65959, Materials Science Forum Vols. 821-823 (2015) pp 47-50, and Journal of Crystal Growth 470 (2017) 154-158. See Japanese Unexamined Patent Application, First Publication No. 2017-65959 relating to the sublimation method, and see Japanese Unexamined Patent Application, First Publication No. 2016-172674 relating to the solution method).

The SiC power device advances to a medium withstand voltage region of which the withstand voltage is in a region of 1 kV, and a high withstand voltage region of which the withstand voltage is in a region of 5 kV, but the p-type silicon carbide single crystal substrate of the low resistivity becomes available, as described above, thereby, a full-scale research on an n-channel SiC-IGBT in an ultrahigh withstand voltage region of which the withstand voltage is 10 kV or more is in the process of beginning. In order to realize the n-channel SiC-IGBT, a p-type silicon carbide bulk growth of low resistivity, and an n-type SiC epitaxial growth on the p-type silicon carbide single crystal substrate of the low resistivity are major factors.

In the ultrahigh withstand voltage power device (ultrahigh withstand voltage region) of 10 kV or more, there is a need for an epitaxial layer of a so-called thick film (100 μm or more), which is an epitaxial layer of which a film thickness is large to be a single digit or more, in comparison with the power device of which the withstand voltage is in a region of 1 kV.

The present inventors perform the n-type SiC epitaxial growth, using the p-type silicon carbide single crystal substrate of the low resistivity, manufacture the silicon carbide epitaxial wafer that is capable of being used for the n-channel SiC-IGBT, and perform an evaluation thereof, thereby, find out problems in such a silicon carbide epitaxial wafer, and solve the problems to complete the present invention.

An object of the present invention is to provide a high quality silicon carbide epitaxial wafer using a p-type silicon carbide single crystal substrate of low resistivity, a method for manufacturing the same, and a silicon carbide semiconductor device.

Representative examples of the present invention are described as follows.

(1) According to a first aspect of the present invention, there is provided a silicon carbide epitaxial wafer including a p-type 4H—SiC single crystal substrate that has a first main surface having an off angle with respect to (0001) plane, and has a resistivity of less than 0.4 Ωcm, and a silicon carbide epitaxial layer that is disposed on the first main surface of the p-type 4H—SiC single crystal substrate, in which an off direction of the off angle is <01-10> direction.

(2) According to a second aspect of the present invention, there is provided a silicon carbide epitaxial wafer including a p-type 4H—SiC single crystal substrate that has a first main surface having an off angle with respect to (0001) plane, and of which the doping concentration of Al is more than 3×10¹⁹ cm⁻³, and a silicon carbide epitaxial layer that is disposed on the first main surface of the p-type 4H—SiC single crystal substrate, in which an off direction of the off angle is <01-10> direction.

(3) In the aspects described above, an interface dislocation density of the silicon carbide epitaxial layer may be 10 cm⁻¹ or less.

(4) In the aspects described above, the first main surface may be (0001) Si plane.

(5) In the aspects described above, the silicon carbide epitaxial layer may be an n-type.

(6) According to a third aspect of the present invention, there is provided a silicon carbide semiconductor device obtained by using the silicon carbide epitaxial wafer according to the aspects described above.

### Advantageous Effects of the Invention

According to the silicon carbide epitaxial wafer of the present invention, it is possible to provide a high quality silicon carbide epitaxial wafer using a p-type silicon carbide single crystal substrate of low resistivity.

### BRIEF DESCRIPTION OF THE DRAWINGS

FIG. 1 is a sectional view schematically showing a silicon carbide epitaxial wafer 10 according to a first embodiment of the present invention.

FIG. 2 is a sectional view schematically showing a silicon carbide epitaxial wafer 20 according to a second embodiment of the present invention.

FIG. 3 is a graph showing a relationship between a doping concentration of Al and resistivity in a p-type 4H—SiC single crystal substrate, and presence or absence (o in case of absence, x in case of presence) of existence of high density interface dislocation of 250 cm⁻¹ or more, regarding a silicon carbide epitaxial wafer of which a manufacturing method and conditions are different from those of the p-type 4H—SiC single crystal substrate.

FIG. 4 is a reflection topographic image of a range of 2 mm×2 mm, in diffraction vector [−1-128], regarding a silicon carbide epitaxial wafer that is obtained using the p-type 4H—SiC single crystal substrate of 4° off in <11-20> direction, which is obtained by a solution method.

FIG. 5 is a reflection topographic image of a silicon carbide epitaxial wafer that is manufactured under conditions which are the same as those of the silicon carbide epitaxial wafer of which the reflection topographic image is shown in FIG. 4, except that a p-type 4H—SiC single crystal substrate of 4° off in <01-10> direction is used.

FIG. 6 is a sectional view schematically showing a silicon carbide semiconductor device 100 according to one embodiment of the present invention.

FIG. 7 is a schematic sectional view showing a method for manufacturing a silicon carbide semiconductor device of the present invention.

FIG. 8 is a schematic sectional view showing the method for manufacturing the silicon carbide semiconductor device of the present invention.

FIG. 9 is a schematic sectional view showing the method for manufacturing the silicon carbide semiconductor device of the present invention.

### DETAILED DESCRIPTION OF THE INVENTION

Hereinafter, the present embodiments will be described in detail with reference to the drawings as appropriate. In the drawings which are used in the following description, in order to easily understand features of the present invention, for the sake of convenience, there is a case where a portion which becomes the feature is shown by being enlarged, or there is a case where a dimension ratio or the like of each configuration component is different from an actual value. A material, a dimension, or the like shown in the following description is an example, the present invention is not limited thereto, and it is possible to carry out the present invention by appropriately modifying the present invention in a range that achieves effects of the present invention.

(Silicon Carbide Epitaxial Wafer)

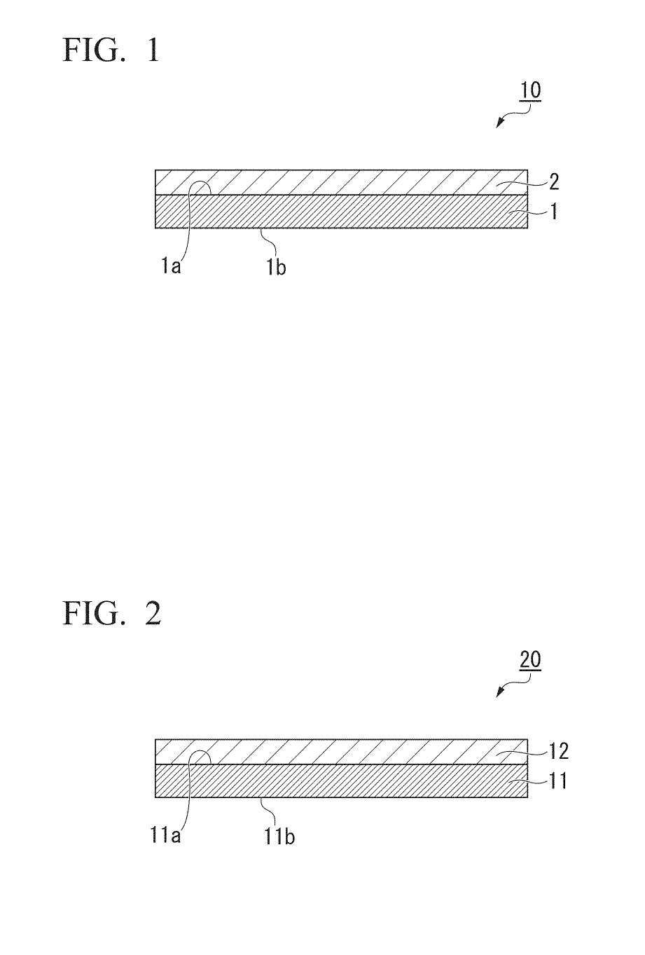

FIG. 1 is a sectional view schematically showing a silicon carbide epitaxial wafer 10 according to a first embodiment of the present invention.

The silicon carbide epitaxial wafer 10 includes a p-type 4H—SiC single crystal substrate 1 that has a first main surface 1a having an off angle with respect to (0001) plane, and is less than 0.4 Ωcm in resistivity, and a silicon carbide epitaxial layer 2 that is disposed on the first main surface 1a of the p-type 4H—SiC single crystal substrate 1, and an off direction of the off angle is <01-10> direction. A second main surface 1b is a surface on which the silicon carbide epitaxial layer 2 is not disposed.

<p-Type 4H—SiC Single Crystal Substrate>

A silicon carbide (SiC) has a lot of crystal polymorphs, but a substrate of the present invention is the 4H—SiC substrate.

As a 4H—SiC single crystal substrate, it is possible to use the 4H—SiC single crystal substrate obtained by being cut out from a silicon carbide bulk crystal which is manufactured by a solution method, a sublimation method, or the like.

As a p-type 4H—SiC single crystal substrate 1, a p-type 4H—SiC epitaxial film may be formed on an n-type 4H—SiC single crystal substrate.

The off direction of the p-type 4H—SiC single crystal substrate 1 is the <01-10> direction.

As long as the effects of the present invention are achieved, the <01-10> direction is permitted to shift. Although being not limited, speaking of a standard, it may be in a range of ±5° or less with respect to the <01-10> direction, it is preferable to be in a range of ±3° or less with respect to the <01-10> direction, and it is further preferable to be in a range of ±1° or less with respect to the <01-10> direction.

The p-type 4H—SiC single crystal substrate 1 is less than 0.4 Ωcm in resistivity, but the resistivity thereof is preferably 0.2 Ωcm or less, more preferably 0.1 Ωcm or less, and further preferably 0.05 Ωcm or less. Although being not limited, the standard value of a lower limit of the resistivity of the p-type 4H—SiC single crystal substrate is 0.02 Ωcm.

As an off angle of the p-type 4H—SiC single crystal substrate, it is possible to use any off angle, but it is preferable that the off angle be small, for example, exceed 0° and be 8° or less, from the viewpoint of cost reduction.

As an acceptor impurity for assigning the p-type, for example, it is possible to use aluminum (Al) or boron (B). In the p-type SiC single crystal substrate, a technique referred to as co-doping that adds both of acceptor and donor impurities is used for a control or the like of the crystal polymorph, and aluminum (Al) of the acceptor impurity and nitrogen (N) of the donor impurity may be added at the same time (Journal of Crystal Growth 470 (2017) 154-158). In this case, the concentration of the acceptor impurity is made be higher than the concentration of the donor impurity, thereby, the SiC single crystal substrate becomes a p-type substrate.

The impurity concentration is a concentration in a case where the resistivity of the p-type 4H—SiC single crystal substrate is made to be less than 0.4 Ωcm.

The thickness of the p-type 4H—SiC single crystal substrate is not particularly limited, but for example, the thickness is 200 μm or more and 700 μm or less, and preferably 300 μm or more and 600 μm or less.

There are many cases where the substrate of which the thickness is 350 μm is used as a 4° off substrate, but the substrate of which the thickness is 500 μm is commercially available.

<Silicon Carbide Epitaxial Layer>

The film thickness of the silicon carbide epitaxial layer is not particularly limited, but if the standard is shown, it is possible to make the film thickness be 0.2 μm or more and 500 μm or less. In a case where the silicon carbide epitaxial wafer of the present invention is used in a SiC device such as an IGBT of which a withstand voltage is 10 kV or more, it is preferable to be a so-called thick film (100 μm or more). This is because the silicon carbide epitaxial wafer which is suitable for a power device of the high withstand voltage is made.

The most suitable film thickness of the silicon carbide epitaxial layer is determined in accordance with design specification of the withstand voltage of the device, and there is a need to be approximately 150 μm, 200 μm, or 250 μm for an ultrahigh withstand voltage device.

If an upper limit thereof is shown, approximately 500 μm is cited, from the viewpoint of difficulty of an epitaxial growth.

It is possible to form the silicon carbide epitaxial layer on either of a Si surface and a C surface of the p-type 4H—SiC single crystal substrate, but it is preferable that the silicon carbide epitaxial layer be formed on the Si surface.

In a case where the silicon carbide epitaxial wafer of the present invention is used in the SiC device such as the IGBT of which the withstand voltage is 10 kV or more, it is possible to make the total thickness (that is, the thickness of the silicon carbide epitaxial wafer) of the p-type 4H—SiC single crystal substrate and the silicon carbide epitaxial layer be 450 μm or more.

For example, a case where the thickness of the p-type 4H—SiC single crystal substrate is 350 and the thickness of the silicon carbide epitaxial layer is 100 μm is equivalent thereto.

In a case where the silicon carbide epitaxial wafer of the present invention is used in the SiC device such as the IGBT of which the withstand voltage is 10 kV or more, it is possible to make the total thickness (that is, the thickness of the silicon carbide epitaxial wafer) of the p-type 4H—SiC single crystal substrate and the silicon carbide epitaxial layer be 600 μm or more.

For example, a case where the thickness of the p-type 4H—SiC single crystal substrate is 350 μm, and the thickness of the silicon carbide epitaxial layer is 250 μm is equivalent thereto.

An outer diameter of the p-type 4H—SiC single crystal substrate is not particularly limited, but it is possible to make the outer diameter be 75 mm or more if the standard is shown.

FIG. 2 is a sectional view schematically showing a silicon carbide epitaxial wafer 20 according to a second embodiment of the present invention.

The silicon carbide epitaxial wafer 20 includes a p-type 4H—SiC single crystal substrate 11 that has a first main surface 11a having an off angle with respect to the (0001) plane, and is more than 3×10¹⁹ cm⁻³ in doping concentration of Al, and a silicon carbide epitaxial layer 12 that is disposed on the first main surface 11a of the p-type 4H—SiC single crystal substrate 11, and an off direction of the off angle is the <01-10> direction. A second main surface 11b is a surface on which the silicon carbide epitaxial layer 12 is not disposed.

The p-type 4H—SiC single crystal substrate 11 is more than 3×10¹⁹ cm⁻³ in doping concentration of Al, but it is preferable to be 6×10¹⁹ cm⁻³ or more, more preferable to be 1×10²⁰ cm⁻³ or more, and further preferable to be 2×10²⁰ cm⁻³ or more. Although being not limited, the standard value of the upper limit of the doping concentration of Al is 6×10²⁰ cm⁻³.

In the silicon carbide epitaxial wafer 20, the description of points that are the same as those of the silicon carbide epitaxial wafer 10 according to the first embodiment will be omitted.

<Comparison by Method for Manufacturing p-Type 4H—SiC Single Crystal Substrate>

(1) Solution Method and Low Resistivity p-Type Substrate, and Silicon Carbide Epitaxial Wafer Using the Same

A p-type 4H—SiC single crystal substrate (thickness: 350 μm) that is 6×10¹⁹ cm⁻³ in doping concentration of Al which is grown by a solution method using a Si—Al solvent, is 0.18 Ωcm in resistivity, and is 4° off in <11-20> direction is used, an n-type SiC epitaxial growth is performed using a CVD method on an Si surface, and a silicon carbide epitaxial wafer is manufactured. The epitaxial growth is performed under conditions that a growth temperature is 1570° C. to 1580° C., a growth pressure is 2.7 kPa, a C/Si ratio is 0.8, and a growth speed is 15 μm/h, the film thickness of the silicon carbide epitaxial layer is 20 μm, and a carrier concentration of the silicon carbide epitaxial layer is 5×10¹⁴ cm⁻³. The silicon carbide epitaxial layer becomes an n-type layer, and nitrogen (N) is doped to be the carrier concentration of a target. Hereinafter, the substrate in this case may be referred to as a solution method and low resistivity p-type substrate, and the silicon carbide epitaxial wafer may be referred to as a silicon carbide epitaxial wafer using the solution method and low resistivity p-type substrate.

(2) Sublimation Method and Low Resistivity p-Type Substrate, and Silicon Carbide Epitaxial Wafer Using the Same

A p-type 4H—SiC single crystal substrate (thickness: 350 μm) that is 1×10²⁰ cm⁻³ in doping concentration of Al which is grown by a sublimation method, is 0.13 Ωcm in resistivity, and is 4° off in the <11-20> direction is used, the n-type SiC epitaxial growth is performed using the CVD method on the Si surface, and a silicon carbide epitaxial wafer is manufactured. The conditions of the epitaxial growth, the film thickness of the silicon carbide epitaxial layer, and the carrier concentration of the silicon carbide epitaxial layer are the same as those of the silicon carbide epitaxial wafer of (1) described above. Hereinafter, the substrate in this case may be referred to as a sublimation method and low resistivity p-type substrate, and the silicon carbide epitaxial wafer may be referred to as a silicon carbide epitaxial wafer using the sublimation method and low resistivity p-type substrate.

(3) Sublimation Method and High Resistivity p-Type Substrate, and Silicon Carbide Epitaxial Wafer Using the Same

A p-type 4H—SiC single crystal substrate (thickness: 350 μm) that is 3×10¹⁹ cm⁻³ in doping concentration of Al which is grown by the sublimation method, is 0.4 Ωcm in resistivity, and is 4° off in the <11-20> direction is used, the n-type SiC epitaxial growth is performed using the CVD method on the Si surface, and a silicon carbide epitaxial wafer is manufactured. The conditions of the epitaxial growth, the film thickness of the silicon carbide epitaxial layer, and the carrier concentration of the silicon carbide epitaxial layer are the same as those of the silicon carbide epitaxial wafer of (1) described above. Hereinafter, the substrate in this case may be referred to as a sublimation method and high resistivity p-type substrate, and the silicon carbide epitaxial wafer may be referred to as a silicon carbide epitaxial wafer using the sublimation method and high resistivity p-type substrate.

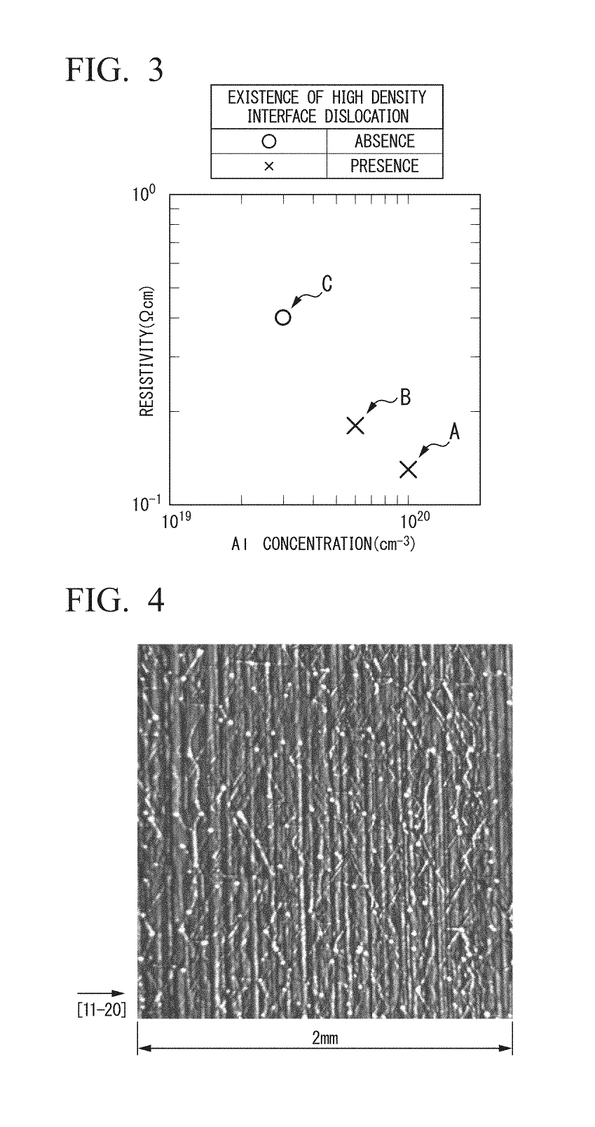

FIG. 3 is a graph showing a relationship between the doping concentration of Al and the resistivity in the p-type 4H—SiC single crystal substrate, and presence or absence (o in case of absence, x in case of presence) of existence of high density interface dislocation of 250 cm⁻¹ or more, regarding the silicon carbide epitaxial wafer (B in FIG. 3) using the solution method and low resistivity p-type substrate, the silicon carbide epitaxial wafer (A in FIG. 3) using the sublimation method and low resistivity p-type substrate, and the silicon carbide epitaxial wafer (C in FIG. 3) using the sublimation method and high resistivity p-type substrate. The density of the interface dislocation in the SiC epitaxial layer is evaluated by a photoluminescence (PL) image using a long path filter of 750 nm.

The doping concentration of Al correlates with the resistivity. If the doping concentration of Al becomes high, the carriers increase, thereby, the resistivity is dropped. If the doping concentration of Al becomes low, the carriers decrease, thereby, the resistivity is raised.

Each interface dislocation density of the silicon carbide epitaxial wafer (B in FIG. 3) using the solution method and low resistivity p-type substrate, the silicon carbide epitaxial wafer (A in FIG. 3) using the sublimation method and low resistivity p-type substrate, and the silicon carbide epitaxial wafer (C in FIG. 3) using the sublimation method and high resistivity p-type substrate is 250 cm⁻¹, 250 cm⁻¹, and 0 cm⁻¹, respectively.

Here, if the interface dislocation exits at an interface between the SiC single crystal substrate and the silicon carbide epitaxial layer, a dislocation half loop with basal plane dislocation is generated in the epitaxial layer. If the dislocation half loop with the basal plane dislocation is generated in the epitaxial layer, and the basal plane dislocation exits in a drive region of the device, the basal plane dislocation extends to a stacking fault due to electrification, and reliability of the SiC device is adversely affected. Therefore, in general, there is a need for a technology of performing the epitaxial growth while reducing the interface dislocation.

In FIG. 3, it is found that threshold values of the doping concentration of Al and the resistivity are present in the presence or absence of the generation of the high density interface dislocation of 250 cm⁻¹ or more, regardless of a method for manufacturing the substrate.

In FIG. 3, the threshold value of the doping concentration of Al is 3 to 6×10¹⁹ cm⁻³, and the threshold value of the resistivity is 0.2 to 0.4 Ωcm.

The present inventors finds out that the interface dislocation of the high density is not generated in the silicon carbide epitaxial wafer using the p-type 4H—SiC single crystal substrate of which Al of the low concentration is doped (for example, 3×10¹⁹ cm⁻³ or less), or the resistivity is high (for example, 0.4 Ωcm or more), which comes to be used in the related art, but the interface dislocation of the high density is generated in the silicon carbide epitaxial wafer using the p-type 4H—SiC single crystal substrate of which Al of the high concentration is doped (for example, more than 3×10¹⁹ cm⁻³), or the resistivity is low (for example, less than 0.4 Ωcm), for the first time.

Such new knowledge is obtained for the first time by which the p-type silicon carbide single crystal substrate of the low resistivity becomes recently available.

The present inventors progress diligent studies in order to solve new problems. As a result, the present inventors conceive of the silicon carbide epitaxial wafer in the present invention.

A cause of the existence of the high density interface dislocation is studied.

Regardless of the method for growing the p-type 4H—SiC single crystal substrate, considering being ruled by the doping concentration of Al, it is assumed to be the cause that a lattice constant difference or a thermal expansion coefficient difference between the p-type 4H—SiC single crystal substrate of the low resistivity to which Al is added at the high concentration and the n-type epitaxial film increases, in comparison with the p-type 4H—SiC single crystal substrate of the high resistivity of which Al of the low concentration is doped, and the n-type epitaxial film in the related art, thereby, stress at a growth interface becomes large.

On the other hand, when the Burgers vector of the basal plane dislocation in the SiC single crystal substrate is parallel to the off direction, the basal plane dislocation in the SiC single crystal substrate is likely to be propagated to the SiC epitaxial layer, that is, there is a report of being less likely to be converted into threading edge dislocation in the SiC epitaxial layer (see Phys. Status Solidi B246 (2009) 1553).

Since the Burgers vector of the basal plane dislocation in the SiC single crystal substrate is in the <11-20> direction, the present inventors decided to evaluate the silicon carbide epitaxial wafer that is manufactured using the p-type 4H—SiC single crystal substrate of the low resistivity, which has the off angle in the <01-10> direction.

<Comparison by Off Direction of p-Type 4H—SiC Single Crystal Substrate>

FIG. 4 shows a reflection topographic image of a range of 2 mm×2 mm, in diffraction vector [−1-128], regarding the silicon carbide epitaxial wafer of (1) described above.

In FIG. 4, a bright line with a contrast expanding in a straight line shape in a direction which is orthogonal to the off direction is the interface dislocation.

It is found that the high density interface dislocation exists over the entire surface of the image. The density of the interface dislocation is 250 cm⁻¹ (50 in the field of view).

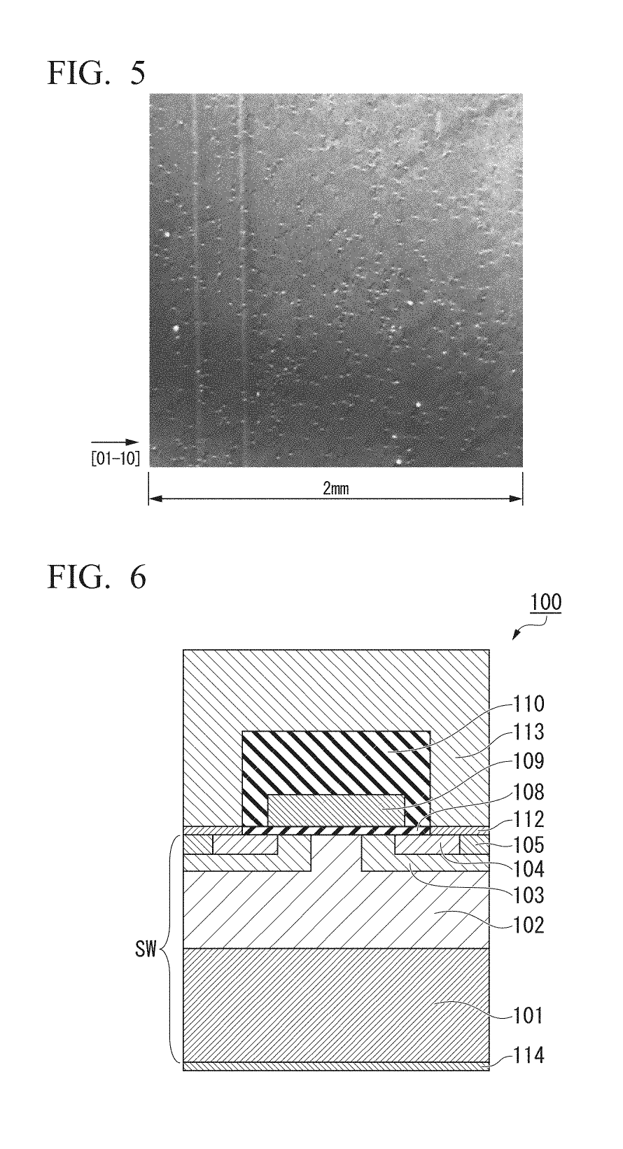

FIG. 5 shows a reflection topographic image of the range of 2 mm×2 mm, in the diffraction vector [−1-128], regarding a silicon carbide epitaxial wafer (may be referred to as a silicon carbide epitaxial wafer using the off substrate in the <01-10> direction, hereinafter) that is manufactured under the conditions which are the same as those of the silicon carbide epitaxial wafer of which the reflection topographic image is shown in FIG. 4, except that the p-type 4H—SiC single crystal substrate of 4° off in the <01-10> direction is used.

The bright line with the contrast expanding in the straight line shape in the direction which is orthogonal to the off direction is the interface dislocation.

In comparison with FIG. 4, it is found that the density of the interface dislocation sharply decreases. The density of the interface dislocation is 10 cm⁻¹ (two in the field of view).

This is considered that the off substrate in the <01-10> direction of which the off direction is not parallel to the Burgers vector <11-20> of the basal plane dislocation in the substrate is used, thereby, the conversion from the basal plane dislocation into the threading edge dislocation is promoted at the epitaxial growth interface, and the interface dislocation density sharply decreases.

As described above, it is found that it is possible to solve the problems of the generation of the high density interface dislocation, by using the off substrate in the <01-10> direction, in replacement of the off substrate in the <11-20> direction, in the silicon carbide epitaxial wafer using the p-type 4H—SiC single crystal substrate of which Al of the high concentration is doped (for example, more than 3×10¹⁹ cm⁻³), or the resistivity is low (for example, less than 0.4 Ωcm) that is found out by the present inventors.

(Silicon Carbide Semiconductor Device)

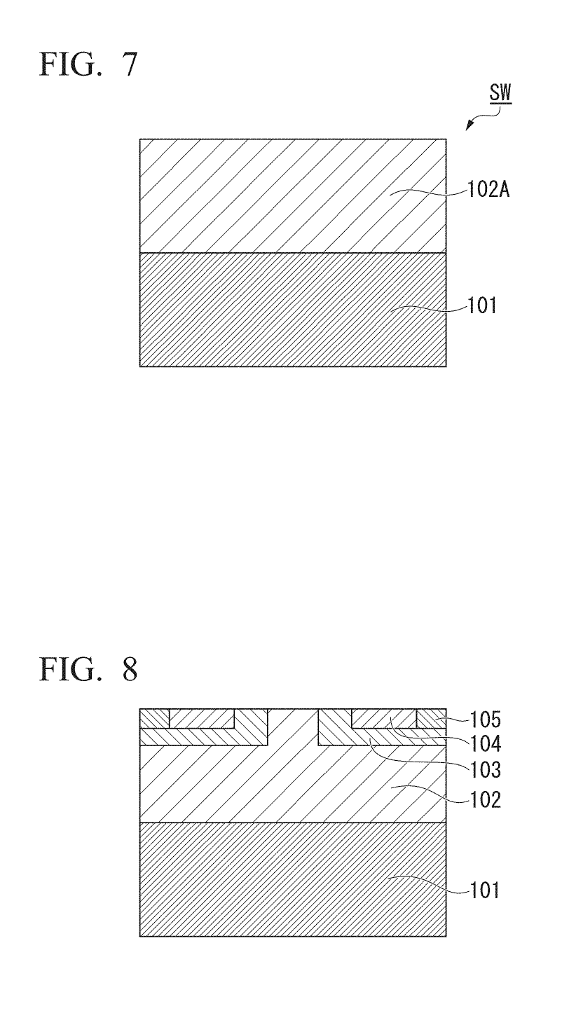

FIG. 6 is a sectional view schematically showing a silicon carbide semiconductor device 100 according to one embodiment of the present invention.

The silicon carbide semiconductor device 100 is an n-channel SiC-IGBT having a planar gate structure, and is manufactured using a silicon carbide epitaxial wafer SW.

The silicon carbide semiconductor device 100 includes a p-type silicon carbide single crystal substrate 101, an n-type epitaxial layer 102, a body region 103, an emitter region 104, a p⁺ region 105, a gate insulating film 108, a gate electrode 109, an interlayer insulating film 110, an emitter contact electrode 112, an emitter wiring 113, and a collector electrode 114.

Each of the p-type silicon carbide single crystal substrate 101, the body region 103, and the p⁺ region 105 has the p-type, and each of the n-type epitaxial layer 102 and the emitter region 104 has the n-type. The impurity concentration of the emitter region 104 is higher than the impurity concentration of the n-type epitaxial layer 102. The impurity concentration of the p⁺ region 105 is higher than the impurity concentration of the body region 103. The body region 103 is disposed on the n-type epitaxial layer 102. The emitter region 104 is disposed on the body region 103 to be separated from the n-type epitaxial layer 102 by the body region 103. The p⁺ region 105 is disposed on the body region 103 to be in contact with the emitter region 104.

The gate insulating film 108 is disposed on the body region 103 to connect the n-type epitaxial layer 102 to the emitter region 104. The gate insulating film 108 is preferably an oxide film, and is a silicon oxide film, for example. The gate electrode 109 is disposed on the gate insulating film 108. The gate electrode 109 is made from a conductor, and is made from polysilicon to which the impurities are added, or Al, for example.

The emitter contact electrode 112 is disposed on each of the emitter region 104 and the p₊ region 105. The emitter contact electrode 112 is an electrode that is connected to each of the emitter region 104 and the p⁺ region 105 in an ohmic manner, and preferably an electrode which is made from a silicide, and is made from a nickel silicide, for example. The emitter wiring 113 is disposed on each of the emitter contact electrode 112 and the interlayer insulating film 110. The interlayer insulating film 110 is disposed to electrically make insulation between the gate electrode 109 and the emitter wiring 113. For example, the interlayer insulating film 110 is a silicon oxide film.

The collector electrode 114 is disposed on a bottom surface side of the p-type silicon carbide single crystal substrate 101. The collector electrode 114 is an electrode that is connected to the p-type silicon carbide single crystal substrate 101 in an ohmic manner, and preferably an electrode which is made from a silicide, and is made from a nickel silicide, for example.

(Method for Manufacturing Silicon Carbide Semiconductor Device)

It is possible to manufacture the silicon carbide semiconductor device of the present invention using known means for forming a film.

The silicon carbide semiconductor device 100 shown in FIG. 6 is used as an example, and a method for manufacturing the silicon carbide semiconductor device of the present invention will be described with reference to FIG. 7 to FIG. 9.

First, as shown in FIG. 7, the silicon carbide epitaxial wafer SW of the present invention including the p-type 4H—SiC single crystal substrate 101, and a silicon carbide epitaxial layer 102A that is disposed on the first main surface of the p-type 4H—SiC single crystal substrate 101, in which the off direction of the off angle is the <01-10> direction, is prepared. For example, the silicon carbide epitaxial wafer SW is the silicon carbide epitaxial wafer 10 shown in FIG. 1, or the silicon carbide epitaxial wafer 20 shown in FIG. 2.

Next, as shown in FIG. 8, the body region 103 having the p-type, and the emitter region 104 having the n-type, which is disposed on the body region 103 to be separated from the drift layer 102 due to the body region 103, are formed in the silicon carbide epitaxial layer 102A by ion implantation. The p⁺ region 105 is formed on the body region 103. The drift layer 102 is a region obtained by excluding the body region 103, the emitter region 104, and the p⁺ region 105, in the silicon carbide epitaxial layer 102A.

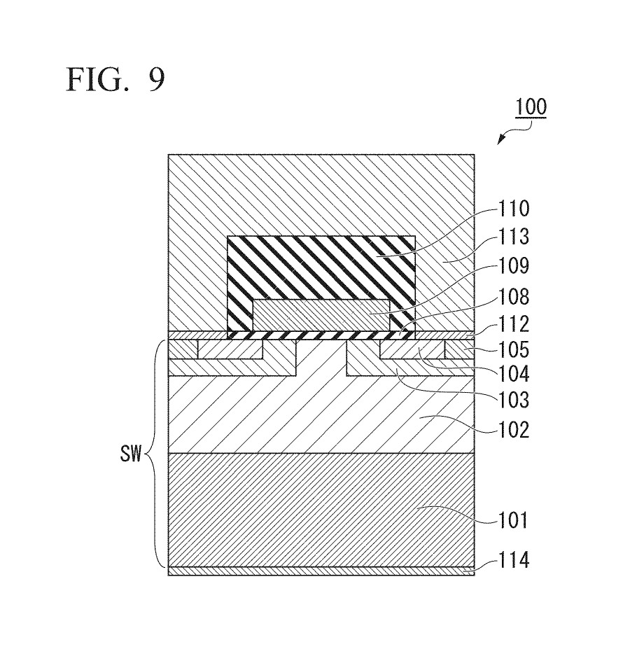

Next, as shown in FIG. 9, the gate insulating film 108 is formed, subsequently, the gate electrode 109 is formed on the gate insulating film 108. Next, the interlayer insulating film 110 is formed. Furthermore, for example, the interlayer insulating film 110 and the gate insulating film 108 corresponding to a region in which the emitter contact electrode 112 ought to be formed, are removed by RIE. The emitter contact electrode 112 is formed on the region in which the interlayer insulating film 110 and the gate insulating film 108 are removed. If the emitter wiring 113 is formed, the silicon carbide semiconductor device 100 is obtained.

While preferred embodiments of the invention have been described and shown above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

### EXPLANATION OF REFERENCES

1, 11: p-type 4H—SiC single crystal substrate
1a, 11a: first main surface
1b, 11b: second main surface
2, 12: silicon carbide epitaxial layer
10, 20, SW: silicon carbide epitaxial wafer
100: silicon carbide semiconductor device

1. A silicon carbide epitaxial wafer comprising:
a p-type 4H—SiC single crystal substrate that has a first main surface having an off angle with respect to (0001) plane, and has a resistivity of less than 0.4 Ωcm; and
a silicon carbide epitaxial layer that is disposed on the first main surface of the p-type 4H—SiC single crystal substrate,
wherein an off direction of the off angle is <01-10> direction.

2. A silicon carbide epitaxial wafer comprising:
a p-type 4H—SiC single crystal substrate that has a first main surface having an off angle with respect to (0001) plane, and of which a doping concentration of Al is more than 3×10¹⁹ cm⁻³; and
a silicon carbide epitaxial layer that is disposed on the first main surface of the p-type 4H—SiC single crystal substrate,
wherein an off direction of the off angle is <01-10> direction.

3. The silicon carbide epitaxial wafer according to claim 1,
wherein an interface dislocation density of the silicon carbide epitaxial layer is 10 cm⁻¹ or less.

4. The silicon carbide epitaxial wafer according to claim 1,
wherein the first main surface is (0001) Si plane.

5. The silicon carbide epitaxial wafer according to claim 1,
wherein the silicon carbide epitaxial layer is an n-type.

6. A silicon carbide semiconductor device obtained by using the silicon carbide epitaxial wafer according to claim 1.

7. The silicon carbide epitaxial wafer according to claim 2,
wherein an interface dislocation density of the silicon carbide epitaxial layer is 10 cm⁻¹ or less.

8. The silicon carbide epitaxial wafer according to claim 2,
wherein the first main surface is (0001) Si plane.

9. The silicon carbide epitaxial wafer according to claim 2,
wherein the silicon carbide epitaxial layer is an n-type.

10. A silicon carbide semiconductor device obtained by using the silicon carbide epitaxial wafer according to claim 2.
